(19) United States
(12) Patent Application Publication
(10) Pub. No.: US 2020/0321751 A1
(43) Pub. Date: Oct. 8, 2020

(54) NETWORK OF QUANTUM CASCADE LASERS WITH ANTIGUIDING BURIED IN A TYPE IV MATERIAL AND WITH SINGLE-LOBE EMISSION

(71) Applicant: THALES, Courbevoie (FR)

(72) Inventors: Simon FERRE, Mont-Saint-Aignan (FR); Mathieu CARRAS, Bures-sur-Yvette (FR)

(21) Appl. No.: 16/303,910

(22) PCT Filed: May 23, 2017
(86) PCT No.: PCT/EP2017/062352

§ 371 Date: Nov. 21, 2018

(30) Foreign Application Priority Data
May 24, 2016 (FR) 1600831

(51) Int. Cl. H01S 5/22; H01S 5/34; H01S 5/40

(52) U.S. Cl. CPC H01S 5/2205; H01S 5/4081; H01S 5/4031; H01S 5/3402

(57) ABSTRACT

A laser includes a network of micro-ridges of quantum cascade lasers of preset emission wavelength, the micro-ridges, which are of preset widths, forming active zones of refractive index n_{za} that are spaced apart from each other by an inter-ridge material of refractive index nₑ, with n_{za}<nₑ. The inter-ridge material is a group-IV material is also provided.

The field of the invention is that of power quantum cascade lasers (power QCLs) emitting in the mid infrared. Power lasers in the mid infrared (MIR) are typically used in optical countermeasures and in spectroscopy.

Among power lasers mention may also be made of optical-parametric-oscillator (OPO) sources and gas (CO₂) lasers. However, unlike these sources, QCLs are a compact, monolithic and robust solution with a high energy efficiency.

It is desired to be able to use an MIR power source both in pulsed regime (with high peak power) and in continuous-wave and quasi-continuous-wave regime.

One known way of increasing power consists in using a single-ridge QCL and increasing the width of the ridge. However, once a certain width is reached, the thermal load becomes too great to be effectively removed, this leading to a drop in performance or even to destruction of the laser. Optical problems also appear with multi-mode operation, which leads to a greatly degraded far field. The record power obtained in continuous-wave regime at room temperature is 5.1 W for a wavelength of 4.6 μm with a ridge width of 8 μm. In pulsed regime, the record is 120 W of peak power for a ridge width of 400 μm at a wavelength of 4.45 μm. For these structures, the far field is not single-lobe (a single peak in the far field) nor monomode and it greatly degrades when the current flowing through the laser is increased.

One way of effectively dissipating the thermal load and achieving monomode emission is to separate a wide ridge into a plurality of optically coupled micro-ridges. This allows lateral dissipation to be increased and the lateral mode to be controlled.

QCL lasers comprising networks of coupled micro-ridges exist that emit at about 4.6 μm and 8.2 μm and the micro-ridges of which are buried in InP:Fe of refractive index nₑ lower than that of the active zones formed by the micro-ridges (n_{za}); a single micro-ridge, when nₑ<n_{za}, supports guided modes. When these ridges are brought closer together, as in the aforementioned configuration, the modes of each micro-ridge couple evanescently, this requiring a spacing between the ridges that is as small as possible in order to guarantee a high coupling. The lasers obtained in this guided-mode configuration all have a double-lobe far field typical of evanescent coupling. Furthermore, their fabrication requires an epitaxial technique that is difficult to implement, not very widespread and expensive, to fill the space between the ridges with the material of index nₑ, which is conventionally InP:Fe. At 8.2 μm, a peak power of 250 mW peak was obtained in pulsed regime with effective ridge widths of 8 μm. It will be recalled that the effective width of a network of micro-ridges is the sum of the widths of its micro-ridges. At 4.6 μm, peak powers of 400 mW have been achieved for effective widths of 16 μm. Continuous-wave or quasi-continuous-wave operation is not recommended because of the thermal load.

Another approach consists in using a material of high index, such that nₑ>n_{za}; anti-guided structures are then spoken of, the ridges not supporting confined modes contrary to the guided mode seen above.

Such structures have been fabricated by replacing the InP:Fe with an InP:Fe/InGaAs bilayer the refractive index of which is higher than that of the micro-ridges forming the active zones. This is not enough to obtain single-lobe lasers. It is necessary to add a mechanism that introduces losses into undesired modes, which has been done by introducing a particular metallization on the device. However, this metallization is a source of degradation in the performance of the laser from the point of view of power.

By adjusting the spacing between the ridges, it is possible to obtain a single-lobe far field with a peak power of 5.5 W (4.5 W in the main lobe) at 8.36 μm with a duty cycle of 0.05% and an effective ridge width of 105 μm, i.e. an average power of only 2.75 mW. The problem with these structures is that the low thermal conductivity resulting from the bilayer and the large width of the laser ridges lead to a poor thermal dissipation, preventing operation in continuous-wave or quasi-continuous-wave regime. In addition, filtering by losses in the metal decreases the gain of the structure and therefore the output power. These components with anti-guiding in the InP:Fe/InGaAs bilayer require a plurality of steps of crystalline-material re-growth, this being expensive, greatly increasing the complexity of fabrication, and decreasing the tolerance to fabrication defects.

Therefore, there remains to this day a need for a power IR laser that simultaneously meets all of the aforementioned requirements, in terms of average optical power and of WPE (permitted by a good thermal dissipation), of single-lobe emission and of cost and ease of fabrication.

More precisely, one subject of the invention is a laser comprising a network of micro-ridges of quantum cascade lasers of preset emission wavelength, the micro-ridges, which are of preset widths, forming active zones of refractive index n_{za} that are spaced apart from each other by an inter-ridge material of refractive index nₑ, with n_{za}<nₑ. It is mainly characterized in that the inter-ridge material is a group-IV material.

According to one feature of the invention, the group-IV material is typically silicon or germanium and the active zones are typically quantum-well heterostructures of III-IV materials.

The use of a group-IV material such as silicon or germanium and of active zones comprising III-V materials makes it possible to obtain a positive index difference (nₑ−n_{za}>0) that may be very large (nₑ−n_{za}>0.1), this thus allowing the laser to emit in anti-guided super modes that concentrate the far-field power into a centered lobe. Practically, it is possible to use an amorphous material that is easier to synthesize in particular on a III-V substrate. Amorphous silicon or germanium are also materials with low losses in the mid infrared, and they create a sufficient heat sink to allow continuous-wave or quasi-continuous-wave operation. Lastly, silicon or germanium are electrical insulators, this being necessary to not short-circuit the active zone.

With respect to evanescent coupling, with which the spacing between the ridges must be as small as possible in order to guarantee a high coupling, coupling by anti-guiding allows the spacings between the ridges to be made larger and thus technological constraints to be relaxed. Furthermore, the spacing between the modes makes it possible to choose the anti-guided mode that it is desired to see lase.

In addition, amorphous silicon or germanium is a material that is much less constraining than InP:Fe or InGaAs in deposition terms, this decreasing the complexity and cost of production.

The spacings between active zones may be identical; likewise, the widths of the micro-ridges may be identical.

With the active zones forming an effective active zone and the network of micro-ridges including two peripheral ridges, said material is advantageously also placed on the external flanks of the peripheral ridges over a width S≥0 determined depending on the spacing D between active zones and on an overlap of the super mode with the effective active zone.

The laser for example has an emission wavelength comprised between 3.5 μm and 10 μm.

The network for example comprises from 4 to 20 micro-ridges.

Another subject of the invention is a process for fabricating a laser such as described, from a stack, on a substrate of refractive index nₛ, of a layer of an active-zone material of refractive index n_{za}, with nₛ<n_{za}, and of a top confinement layer of refractive index n_{cs}, with n_{cs}<n_{za}, which comprises a step of etching said layers to the substrate in order to form the micro-ridges on the substrate, characterized in that it furthermore includes the following steps:
a) depositing, in a single layer, the group-IV material (2) on the micro-ridges and the substrate,
a) removing the group-IV material deposited on the micro-ridges and on the substrate while leaving said material between the micro-ridges and on the external flanks of the peripheral micro-ridges over a preset width S,
b) depositing a dielectric passivating layer on the edges of the material and on the substrate, and in other portions of the component if necessary,
c) depositing a metal contact layer.

Other features and advantages of the invention will become apparent on reading the following detailed description, which is given by way of nonlimiting example and with reference to the appended drawings, in which:

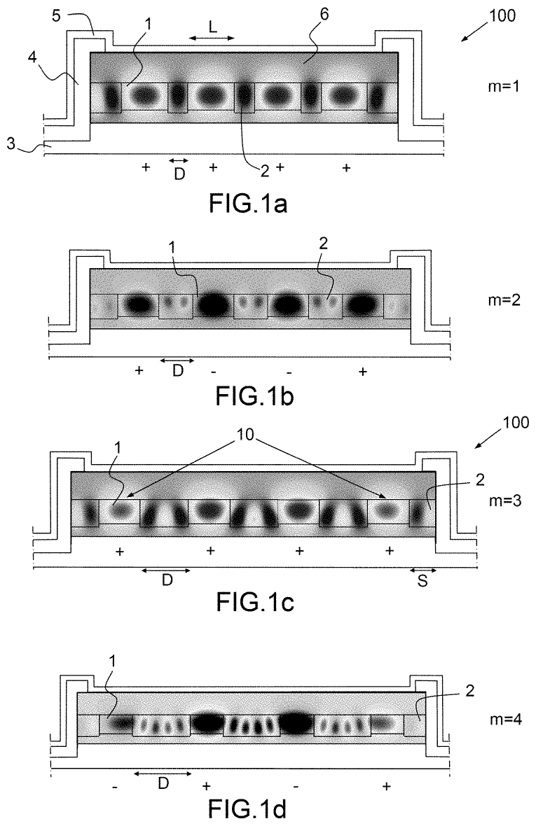

FIGS. 1a to 1d schematically show examples of symmetric anti-guided super-mode lasers according to the invention (FIGS. 1a and 1c) and examples of anti-symmetric anti-guided super-mode lasers (FIGS. 1b and 1d),

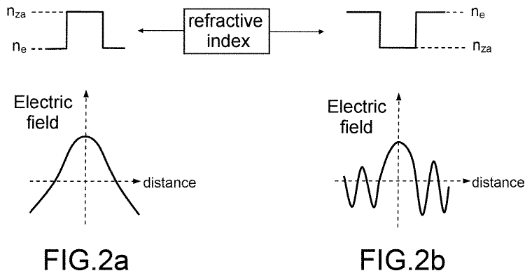

FIGS. 2a and 2b schematically illustrate, for a single ridge, a guided mode (FIG. 2a) and an anti-guided mode (FIG. 2b), with the refractive indices (at the top of the figures), and the amplitude of the corresponding electric field (at the bottom of the figures),

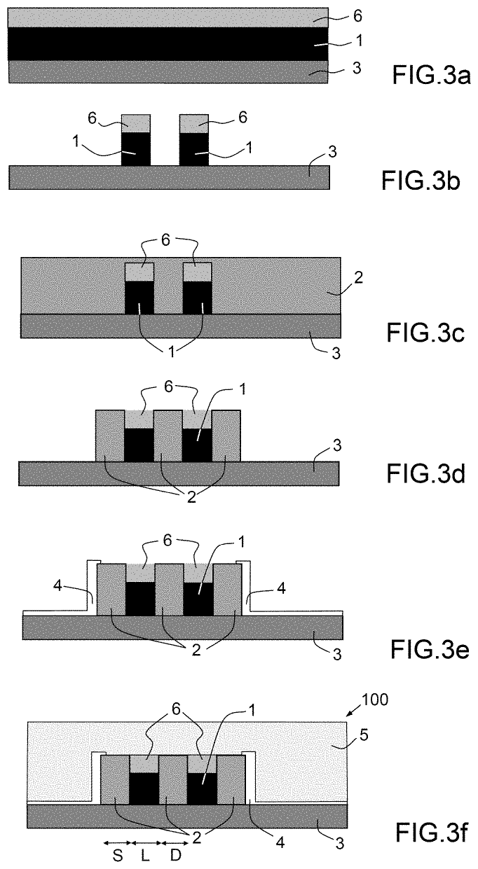

FIGS. 3a to 3f schematically illustrate various fabricating steps of a laser according to the invention,

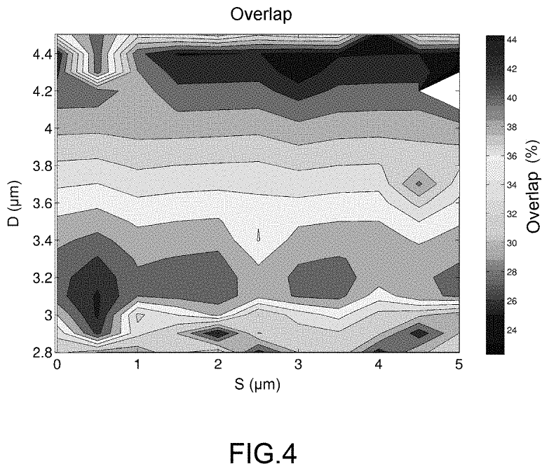

FIG. 4 illustrates the relationship between the distance D between ridges, the thickness S of the material on the external flanks and the overlap of the super mode with the active zones.

In all the figures, elements that are the same have been referenced with the same references.

Insofar as the device may be positioned with other orientations, the directional terminology is indicated by way of illustration and is nonlimiting.

With reference to FIGS. 1a and 1c, an example of a laser 100 according to the invention will now be described. It includes a network of micro-ridges of quantum cascade lasers of preset emission wavelength λ. The micro-ridges, which are of preset widths L₁, . . . , L_{K} (K being the number of micro-ridges) that may be, but are not necessarily, identical for all the micro-ridges (L₁=L_{K}=L), form active zones 1 of refractive index n_{za} that are spaced apart from one another by a width (or spacing) D filled with an inter-ridge material 2 of refractive index nₑ. These spacings may be identical but are not necessarily. So as to obtain a network that produces anti-guided super modes, n_{za}<nₑ. The inter-ridge material is a group-IV material such as silicon or germanium and each spacing D between two adjacent micro-ridges (or two adjacent active zones) is determined on the basis of the wavelength λ, of all the widths L₁, . . . , L_{K} of the micro-ridges and of the refractive indices n_{za} and nₑ in order to obtain a symmetric anti-guided super mode. The expression “super mode” is understood to mean the resultant mode of the whole laser 100. The permitted super modes are, to the first order, linear combinations of the modes of the active zones 1 alone. The super mode favored is the super mode that has the highest modal gain (and therefore the largest overlap) with that of the active zone.

It will be recalled that when n_{za}>nₑ, each active zone 1 supports a guided mode and the electric field decreases exponentially as a function of the distance measured from the core of the active zone, as illustrated in FIG. 2a for a single ridge. This is the case for evanescent coupling between narrow ridges separated from one another by InP:Fe: the widths L₁, . . . , L_{K}, of the ridges are chosen to be sufficiently narrow that, considered separately, each of the ridges supports only the fundamental mode. It is sinusoidal in the active zone and decreases exponentially in the InP:Fe. With a plurality of ridges, the super modes are, to a first approximation, linear combinations of the modes of the ridges considered separately. The antisymmetric super mode is favored (the field in the active zones changes sign between nearest neighbors: +−+−+−, . . . ), this giving a double-lobe far field. The spacing between the micro-ridges then has an influence only on the strength of the coupling therebetween.

By filling the space between the micro-ridges with a group-IV material such as silicon, the existence of anti-guided super modes is made possible, the optical index of silicon being higher than that of the active zone (n_{za}<nₑ). In this case, the mode of the individual ridges is sinusoidal inside the active zone but also outside, in the silicon, with a smaller amplitude, as may be seen in FIG. 2b for a single ridge; leaky modes or leaky waves are then spoken of. In this case, the spacing between the micro-ridges has a different impact to that played in the guided-mode micro-ridge configuration. Specifically, the resonance of the symmetric anti-guided super modes (the field in the active zones is of invariant sign) and of the antisymmetric anti-guided super modes (the field in the active zones changes sign between nearest neighbors) is theoretically obtained for an inter-ridge space D given by:

$$D = \frac{m {λ}_{leak}}{2}$$

$${λ}_{leak} = \frac{λ}{\sqrt{( {n}_{S i}^{2} - {n}_{ZA}^{2} + {( \frac{λ}{2 L} )}^{2} )}}$$

when the spacings are identical and where m is a positive integer that is defined as the number of extrema in the oscillation between the micro-ridges, n_{Si} (or nₑ) and n_{za} are the refractive indices of the group-IV material and of the active zone, respectively, λ is the emission wavelength of the laser 100, λₗₑₐₖ is the spatial periodicity of the portion of the super mode oscillating between two ridges, and L is the width of the micro-ridges, which width is identical for all the ridges (L₁=L_{K}=L).

For uneven m, the symmetric super mode is favored, as illustrated in FIGS. 1a and 1c, and for even m, the antisymmetric super mode is favored, as illustrated in FIGS. 1b and 1d.

When the widths of the micro-ridges vary from one ridge to the next, each spacing D between two micro-ridges is determined by simulation of the optical mode so that the overlap of the desired mode with the adjacent active zones is maximal.

If only the group-IV material is left on the edges of the peripheral micro-ridges 10 shown in FIGS. 1a to 1d, the super mode will also oscillate in all this region, this decreasing the overlap with the active zone and therefore the modal gain. To avoid this, excess group-IV material is etched in order to leave only a narrow zone on the external flanks of the peripheral ridges, as shown in FIGS. 1a to 1d and in FIG. 3. By adjusting the thickness S of this zone, it is possible to change the overlap and the nature of the dominant super mode. FIG. 4 shows the overlap of the super mode having the maximum overlap as a function of S (x-axis) and of the distance D between the micro-ridges (y-axis). For this simulation, L=2 μm, λ=4.5 μm, there are 8 micro-ridges, D varies from 2.8 μm to 4.5 μm and S varies from 0 μm to 5 μm. It may be seen that even if the resonance is always about a given distance D between the micro-ridges of 3.1 μm in our simulation, the value of the overlap of the dominant super mode may fluctuate greatly with S. It is maximal for a nonzero S value (S=0.5 in our simulation) and tends to decrease on the whole when S increases because the super mode is allowed to make more oscillations outside of the active zone. The periodicity of the maxima is related to that of the oscillations of the super mode in this region. This corroborates the fact that anti-guided coupling is more sensitive to lateral losses than evanescent coupling, the field being stronger at the edge of the component, and that these losses may be used to filter undesirable super modes.

D and S may therefore be chosen by calculation and simulation to obtain the desired emission super mode.

To fabricate an anti-guided super-mode laser with a single-lobe emission, it is possible to proceed in the following way described with reference to FIGS. 1b, 1d and 3a-3f, starting with an InP or GaAs substrate 3 of refractive index nₛ<n_{za} in lieu of bottom confinement layer of the mode of the active zones 1. The substrate typically has a thickness comprised between 100 μm and 1 mm. On the substrate, a stack of the following layers is deposited: a layer of a material of the active zone 1, of refractive index n_{za} and of thickness comprised between 300 nm and 10 μm; and a top confinement layer 6 of thickness comprised between 2 and 10 μm, which may consist of the same material as the substrate but does not necessarily, as shown in FIG. 3a. The refractive index n_{cs} of this top confinement layer is such that n_{cs}<n_{za}. The layer of material of the active zones is a quantum-well heterostructure of III-V materials, such as AlInAs, GaInAs, AlAs, AlGaAs, GaAs.

These two last layers are etched to the substrate in order to form micro-ridges, each micro-ridge being intended to form an active zone 1 covered with a top confinement layer 6, as shown in FIG. 3b.

A group-IV material 2 of refractive index nₑ, with n_{za}<nₑ, is deposited in a single layer on the micro-ridges and on the substrate in order to bury the micro-ridges in said material, as shown in FIG. 3c. Practically, an amorphous group-IV material 2 is used, which is easier to synthesize in particular on a III-V substrate. This deposition is advantageously carried out by vapor deposition in order to obtain a thick and conformal deposit (of about 1 to 5 μm) or by atomic layer deposition.

The amorphous material 2 deposited on the micro-ridges is removed and that deposited on the substrate (except between the micro-ridges) is also removed, and preferably partially removed so as to leave the amorphous material on the external flanks of the peripheral micro-ridges over a preset width S, as shown in FIG. 3d. This material 2 is therefore present between the micro-ridges and optionally on these external flanks. This removal is carried out by chemical-mechanical polishing and/or by wet or dry etching; mention may be made, by way of example of dry etching, of reactive-ion etching using an inductively coupled plasma (or RIE-ICP). However, it is possible for S=0 and, in this case, the amorphous group-IV material is entirely removed from the substrate except of course between the micro-ridges.

Next, as shown in FIG. 3e, a dielectric passivating layer 4 of thickness comprised between 100 nm and 1.5 μm, such as of silica (SiO₂) or of silicon nitride (Si₃N₄), is deposited on the edges of the material 2 (but not on the peripheral micro-ridges) and on the substrate 3, before a metal contact 5, such as an alloy based on gold (titanium/platinum/gold (Ti/Pt/Au) or gold/germanium/nickel/gold (AuGe/Ni/Au) for example) of total thickness comprised between 100 nm and 600 nm is deposited, as shown in FIG. 3f.

This dielectric passivating layer 4 may also be deposited on the material 2.

The main fields of exploitation for power lasers in the mid infrared are for example optical countermeasures and spectroscopy.

1. A laser comprising a network of micro-ridges of quantum cascade lasers of preset emission wavelength, the micro-ridges, which are of preset widths, forming active zones of refractive index n_{za} that are spaced apart from each other by an inter-ridge material of refractive index nₑ, with n_{za}<nₑ, wherein the inter-ridge material is a group-IV material.

2. The laser as claimed in claim 1, wherein the spacings between active zones are identical and/or the widths of the micro-ridges are identical.

3. The laser as claimed in claim 1, wherein the widths L of the micro-ridges are identical and the spacings D are identical and determined by
$$D = \frac{m {λ}_{leak}}{2}$$
$${λ}_{leak} = \frac{λ}{\sqrt{( {n}_{S i}^{2} - {n}_{ZA}^{2} + {( \frac{λ}{2 L} )}^{2} )}}$$
where m is an uneven positive integer that is defined as the number of extrema in one oscillation between the micro-ridges, and λₗₑₐₖ is the spatial periodicity of the portion of the super mode oscillating between two ridges.

4. The laser as claimed in claim 1, wherein the group-IV material is silicon or germanium.

5. The laser as claimed in claim 1, wherein the group-IV material is amorphous.

6. The laser as claimed in claim 1, wherein with the active zones forming an effective active zone and the network of micro-ridges including two peripheral ridges, said group-IV material is also placed on the external flanks of the peripheral ridges over a width S≥0 determined depending on the spacings between active zones and on an overlap of the super mode with the effective active zone.

7. The laser as claimed in claim 1, wherein the active zones are heterostructures of III-IV materials.

8. The laser as claimed in claim 1, wherein the laser has an emission wavelength comprised between 3.5 μm and 10 μm.

9. The laser as claimed in claim 1, wherein the network comprises from 4 to 20 micro-ridges.

10. A process for fabricating a laser as claimed in claim 1, from a stack, on a substrate of refractive index nₛ, of a layer of an active-zone material of refractive index n_{za}, with nₛ<n_{za}, and of a top confinement layer of refractive index n_{cs}, with n_{cs}<n_{za}, which comprises a step of etching said layers to the substrate in order to form the micro-ridges on the substrate, wherein it furthermore includes the following steps:
depositing, in a single layer, the group-IV material on the micro-ridges and the substrate,
removing the group-IV material deposited on the micro-ridges and on the substrate while leaving said material between the micro-ridges and on the external flanks of the peripheral micro-ridges over a preset width,
depositing a dielectric passivating layer on the edges of the material and on the substrate,
depositing a metal contact layer.

11. The process for fabricating a laser as claimed in claim 1, wherein S=0.

12. The process for fabricating a laser as claimed in claim 10, wherein step a) is carried out by vapor deposition or by atomic layer deposition.

13. The process for fabricating a laser as claimed in claim 10, wherein step b) is carried out by chemical-mechanical polishing and/or by dry or wet etching.

14. The process for fabricating a laser as claimed in claim 10, wherein that the substrate and the top confinement layer are made of InP or GaAs.
